(19) United States
(12) Patent Application Publication
(10) Pub. No.: US 2024/0313712 A1
(43) Pub. Date: Sep. 19, 2024

(54) SOUND REINFORCEMENT SYSTEM AND METHOD FOR THE OPERATION THEREOF

(71) Applicant: Robert Bosch GmbH, Stuttgart (DE)

(72) Inventors: Fredi Palm, Langwedel (DE); Gregor Sauer, Straubing (DE); Josef Plager, Bogen (DE); Tobias Kieser, Straubing (DE)

(21) Appl. No.: 18/576,152

(22) PCT Filed: Jun. 29, 2022
(86) PCT No.: PCT/EP2022/067905

§ 371 Date: Jan. 3, 2024

(30) Foreign Application Priority Data
Jul. 6, 2021 (DE) 10 2021 207 056.6

(51) Int. Cl. H03F 1/52; H03F 3/72

(52) U.S. Cl. CPC H03F 1/526; H03F 3/72; H03F 2200/03; H03F 2203/7221; H03F 2203/7224

(57) ABSTRACT

The invention relates to a sound reinforcement system (400) comprising a loudspeaker (130) and two audio amplifiers (410, 410′), wherein: each audio amplifier (410, 410′) is equipped with an output relay (214), which extends to an amplifier output terminal (116) of the associated audio amplifier, as well as a ground output terminal (118); each of two terminals of the loudspeaker (130) is connected to one of the amplifier output terminals; the ground output terminals (118) of the two audio amplifiers (410, 410′) are connected to one another and/or to ground. The invention also relates to a method for operating a sound reinforcement system (400) of said type.

### BACKGROUND

The present invention relates to a sound reinforcement system having at least one loudspeaker, and to a method of operating a sound reinforcement system.

Sound reinforcement systems are used, for example, for the acoustic irradiation of rooms or outdoor areas; this can be both with music but also for targeted announcements or the like. For this purpose, a sound reinforcement system is equipped with an amplifier and one or more loudspeakers. From DE 10 2019 208 461 A1, for example, a sound reinforcement system is known.

### SUMMARY

According to the invention, a sound reinforcement system with a loudspeaker, as well as a method for operating a sound reinforcement system with the features of the independent patent claims are proposed. Advantageous embodiments are the subject matter of the dependent claims and of the following description.

The invention deals with sound reinforcement systems and there in particular with amplifiers via which one or more loudspeakers are controlled. For sound reinforcement systems used as voice alarm systems (for important announcements during evacuations, for example), fail-safety is of particular importance. Under all circumstances, it should be prevented that in case of an emergency people cannot be evacuated optimally due to the failure of a sound reinforcement system. Various standards (e.g., the VDE 0833 or EN54 series of standards), local installation regulations and/or also customer requirements make, for example, different specifications as to how and to what extent a certain failure safety can or must be achieved.

In order to ensure fail-safety of an audio system such as a sound reinforcement system, different concepts can be considered. It is conceivable, for example (as an extreme case), that two independent, parallel voice alarm systems (sound reinforcement systems) are installed in a building, a sports facility (e.g., in a stadium or elsewhere), or similar. In the event of failure of one of the two systems, the second or redundant system can still ensure full function. However, from a cost standpoint, it is preferable to install or use only a voice alerting system (also referred to as SAA) in which certain components or elements are designed or provided for redundancy.

One way to provide for some redundancy is, for example, a battery supply that maintains the operation of the voice alarm system in the event of a failure of the mains voltage supply (as a power supply source). So-called emergency amplifiers can also be used, which take over the function of a regular amplifier of the voice alarm system in case of failure. A failure of an amplifier can be detected, for example, by the absence of a pilot tone, whereupon the SAA switches to an emergency amplifier. This usually requires complex, additional circuitry.

Likewise, a redundant design of the loudspeakers or loudspeaker lines (these are several loudspeakers connected to one line or pair of lines, which are usually controlled by an amplifier) can be considered, a so-called A/B cabling. In larger systems, for example, the aim can be to ensure that the so-called speech intelligibility index (STI) does not fall below a specified minimum value even if one or more loudspeakers or amplifiers fail, by mixing the sound sections or sound frequency ranges operated by an amplifier.

The present invention also deals with a redundancy concept for audio amplifiers (these are power amplifiers for the audio range, i.e., for amplifying audio signals, in particular so-called prosound amplifiers with reproduction even in the bass range <100 Hz). This takes advantage of the fact that these audio amplifiers usually have an integrated output relay. Such an output relay then extends to the amplifier output terminal, to which speakers or a speaker line can be connected. It thus connects the direct amplifying output of the audio amplifier to the terminal for the loudspeaker. Such audio amplifiers with output relays are often used, for example, in so-called professional sound reinforcement systems or PA systems (public address sound reinforcement systems). The output relay is then used, for example, to prevent switch-on noises and to be able to disconnect the loudspeakers from the amplifier in the event of a fault.

In principle, such an output relay can be implemented as a normally closed contact or as a changeover switch. With a normally closed contact, the output relay is closed during regular operation of the audio amplifier, i.e., when it is active and outputs a signal. This means that the signal is present at the amplifier output terminal. When the audio amplifier is switched to inactive, the output relay is opened; the speaker lines are then disconnected. This means that a redundant parallel connection of two amplifiers is possible in principle. In the case of a changeover switch, however, the output relay is switched over when the audio amplifier is switched to inactive, so that on the output side the amplifier output terminal is connected, for example, to a ground terminal or ground output terminal of the audio amplifier; the loudspeaker lines are then short-circuited and are connected to ground, which has acoustic advantages.

Within the scope of the invention, a sound reinforcement system with a loudspeaker and two such audio amplifiers, each with an output relay, is now proposed, wherein the output relays are configured in particular as changeover switches, as well as their operation. Each of two terminals of the speaker is thereby connected to one of the amplifier output terminals of the changeover switches, respectively, and the ground output terminals of the changeover switches of the two audio amplifiers are connected to one another and/or to ground. A changeover switch is also called a toggle switch or changeover contact. The changeover switch is equipped with at least three terminals, the changeover switch being configured in such a way that a center terminal is connected as the first terminal in the rest position to the second terminal “closed in rest position” and is connected in the other position to the third terminal “open in rest position”. In particular, the center terminal of the changeover switch is configured as the amplifier output terminal. Preferably, the second terminal and/or in particular the third terminal is configured as a ground output terminal and is connected to ground.

By means of the invention, redundancy for audio amplifiers of a sound reinforcement system can be created in a simple manner, wherein the system remains operational even if one amplifier fails. No complex controls or interconnections are necessary. In particular, no external additional circuitry (relay sets) is required; rather, simple switching/control is achieved, especially by integration into the amplifiers.

The sound reinforcement system, and thus each of the two audio amplifiers, is operated such that when it is active, the output relay is closed so that a signal (output signal) is present at the amplifier output terminal, and when it is inactive, the output relay is switched such that no signal is present at the amplifier output terminal. It is understood that at least when an audio amplifier is switched to active, a corresponding power supply of the audio amplifier is necessary; in addition, a corresponding input signal (e.g., speech, music) must be supplied, which is then amplified and output as an output signal.

The sound reinforcement system is then operated in such a way that, when at least one of the two audio amplifiers is switched to active (and thus then outputs a signal which is present at the associated amplifier output terminal), and when a switched-to-active audio amplifier becomes inactive, the respective other audio amplifier is automatically operated in such a way that a signal with a higher output voltage than before is present at the associated amplifier output terminal. In this context, the fact that a switched-to-active audio amplifier becomes inactive means in particular that this audio amplifier no longer outputs or can no longer output a signal, e.g., due to a defect or error or a failure of its power supply, and thus becomes (passively, so to speak) inactive or is switched to inactive.

In particular, this may comprise at least two preferred options or variants. One of them is that the other audio amplifier is initially switched to inactive (then no signal is output from this audio amplifier at all), and this one is then automatically switched to active when the other one becomes inactive. In other words, initially only one of the two audio amplifiers is active, while the other is inactive. This means that for the audio amplifier that is switched to active, the output relay is closed quite regularly, so that there is a signal at the amplifier output terminal. On the other hand, in the case of the audio amplifier that is (deliberately) switched to inactive, the output relay is correspondingly at a different contact (normally closed contact if it is configured as a changeover switch), so that no signal is present at its amplifier output terminal. This applies, e.g., in spite of a power supply applied to the audio amplifier and also a possibly applied input signal which is to be amplified. For example, the output relay of the audio amplifier in question can be specifically switched over for this purpose.

In order to achieve automatic activation of the previously inactive audio amplifier, a logic (logic circuit or other circuitry) can be provided, for example, which closes the output relay of the other audio amplifier when the output relay of the audio amplifier that becomes inactive is switched over, e.g., due to a defect or failure of the power supply (the output relay is de-energized in this case, for example, and switches over automatically). It is conceivable, for example, that suitable circuitry is used to ensure that the closed output relay of the initially active audio amplifier switches the output relay of the other, inactive audio amplifier via a further, simple relay.

In particular, it is envisaged that in this variant both audio amplifiers are of the same type, so that each of the two is optionally used as active or optionally as inactive and thus as redundant audio amplifier. It is also expedient if a role of active and inactive audio amplifier is exchanged in the sound reinforcement system at predetermined and/or regular, temporal intervals, i.e., if the two audio amplifiers are switched between active and inactive at predetermined and/or regular, temporal intervals. Thus, both audio amplifiers are equally loaded. This can be done by a control, circuit, or computing unit integrated into the sound reinforcement system (or an audio amplifier arrangement comprising the two audio amplifiers), but a higher-level control or other computing unit is also conceivable.

Another preferred possibility is that both audio amplifiers are each switched to active, in such a way that a signal with less than a full output voltage is present at the associated amplifier output terminal. If one of the two switched-to-active audio amplifiers then becomes inactive (e.g., due to a defect), the respective other audio amplifier is automatically operated in such a way that a signal with a higher output voltage than before, in particular the full output voltage, is present at the associated amplifier output terminal. In this case, one of the two audio amplifiers outputs an inverted signal (i.e., with reversed polarity) compared to the other audio amplifier (however, both audio amplifiers can be of the same design). This ensures that the loudspeaker is always controlled in phase, regardless of whether one or both audio amplifiers are currently active. This also applies accordingly to the first option.

In this way, the two audio amplifiers are used together to output a desired signal and apply it to the speaker. The loudspeaker is controlled with the difference of the output voltage of the two audio amplifiers. For example, each of the two audio amplifiers can output 50% of a desired level; if one of the two audio amplifiers fails, the other then expediently outputs 100% of the desired level (the desired level thus corresponds to the full output voltage). For this purpose, a static signal line can be provided, for example, by which one audio amplifier detects that the other has failed (become inactive) and can thus increase the output power for the full output voltage.

Preferably, the two audio amplifiers are set up in such a way that one of the two audio amplifiers outputs a signal at the associated amplifier output terminal that is inverted with respect to the other audio amplifier. In this way, regular operation and emergency operation or backup operation can be ensured with only one functioning audio amplifier for both of the preferred embodiments described.

As already mentioned, the two audio amplifiers each have a ground output terminal. Then, it is preferably provided that the output relays each connect the associated amplifier output terminal to the associated ground output terminal, and in particular automatically when the associated audio amplifier is inactive. This ensures that even if an audio amplifier fails, the amplifier output terminal is connected to ground and poses no danger. In addition, the aforementioned, acoustic advantages are achieved, but still the proposed redundancy is possible. At the same time, a ground fault can be realized for the loudspeaker if only one audio amplifier is active.

By connecting the ground output terminals of both audio amplifiers (directly or via ground), it can be achieved that in case of an inactive audio amplifier and output relays configured as changeover switches, the terminal of the loudspeaker connected to the inactive audio amplifier as well as the corresponding pole of the amplifier output are connected to ground.

Preferably, the two audio amplifiers can be connected to different power supply sources from each other and, in particular, are also connected during operation. This can provide further redundancy, especially in the event of failure of a power supply source.

A particular advantage of the invention is that a redundant emergency concept for audio amplifiers can be achieved by clever interconnection of the output relays which are present and integrated anyway. Other components such as an external emergency changeover unit, on the other hand, are not required. As mentioned, emergency amplifiers can be used, for example, in voice alarm systems in case of amplifier failure. A so-called “looping in” of the emergency amplifier can be achieved by means of relays. While this can be realized comparatively inexpensively with the moderate outputs of pure voice alarm systems (e.g., by means of a relay unit connected in between), so-called prosound amplifiers, as they are used in particular with public address sound reinforcement systems or professional sound reinforcement systems, place high demands on the relays for an emergency concept due to the high output powers. The associated cost makes an emergency concept for prosound amplifiers unattractive.

In contrast, the present invention provides a particularly simple but effective redundant emergency concept, especially for prosound amplifiers without external active electronics or relays.

The present invention is particularly advantageous—but not restricted to this—for sound reinforcement systems whose main function is to provide the public with audio signals that are not relevant to safety (so-called public address sound reinforcement systems or professional sound reinforcement systems). A typical example is the sound reinforcement system in a soccer stadium or any other stadium, which, for example, allows the stadium announcer to interact with the audience and enables music reproduction in high quality. Often, such systems are called prosound systems, because they provide sound reinforcement of professional quality and, if necessary, with high and maximum volume. The failure of a prosound system is usually undesirable. If a prosound system is also to be used for evacuation purposes in the event of danger (e.g., fire, bomb threat, etc.), the requirements mentioned at the beginning regarding redundancy are necessary.

Complicating matters further is the fact that prosound amplifiers typically must deliver significantly higher output powers (e.g., a factor of ten higher) than evacuation-only amplifiers. This is due to the fact that prosound systems have to deliver the most power in the bass range (about 30 to 100 Hz) due to the spectral power distribution of typical music signals. This frequency range is deliberately omitted from (simpler) evacuation amplifiers, since it does not provide any added value for speech intelligibility. Despite the special advantages for professional sound reinforcement systems, the invention can also be used for (simple) voice alarm systems.

Although the operation of one loudspeaker has been described above, other loudspeakers can also be operated with an amplifier arrangement, e.g., several parallel loudspeakers or entire loudspeaker lines. The simple redundancy principle for prosound amplifiers allows the system design to better utilize the performance of the audio amplifiers. For example, several loudspeakers can be connected in parallel to one amplifier channel, because if one audio amplifier fails, there is no need to fear the failure of many loudspeakers, since the second audio amplifier takes over in each case. When assigning loudspeakers to loudspeaker lines, there is no need to consider effects in case of failure of an audio amplifier, since there is always a redundant audio amplifier. The proposed emergency concept also allows audio amplifiers with more channels to be used without concerns of loss of a larger sound reinforcement area in the event of a fault. In such a case, each of the two audio amplifiers may have two or more channels each, with each channel being equipped with an output terminal and associated circuitry as explained (including output relays). One ground output terminal, on the other hand, can be used jointly for several channels.

In a simple case, the redundancy concept can be implemented as stand-alone by the two audio amplifiers or the audio amplifier arrangement or sound reinforcement system without additional higher-level control logic. However, a higher-level control unit can also be provided, for example, which can report failed power amplifiers and audio amplifiers. The failed audio amplifier can be replaced to restore the redundant emergency concept.

### BRIEF DESCRIPTION OF THE DRAWINGS

Further advantages and embodiments of the invention emerge from the description and the accompanying drawing.

The invention is illustrated schematically in the drawing on the basis of exemplary embodiments and is described below with reference to the drawing.

FIG. 1 schematically shows a sound reinforcement system with an audio amplifier to explain the invention.

FIG. 2 schematically shows another sound reinforcement system with a different audio amplifier to explain the invention.

FIG. 3 schematically shows another sound reinforcement system with two audio amplifiers to explain the invention.

FIG. 4 schematically shows a sound reinforcement system according to the invention in a preferred embodiment.

FIG. 5 schematically shows a sound reinforcement system according to the invention in a further preferred embodiment.

### DETAILED DESCRIPTION

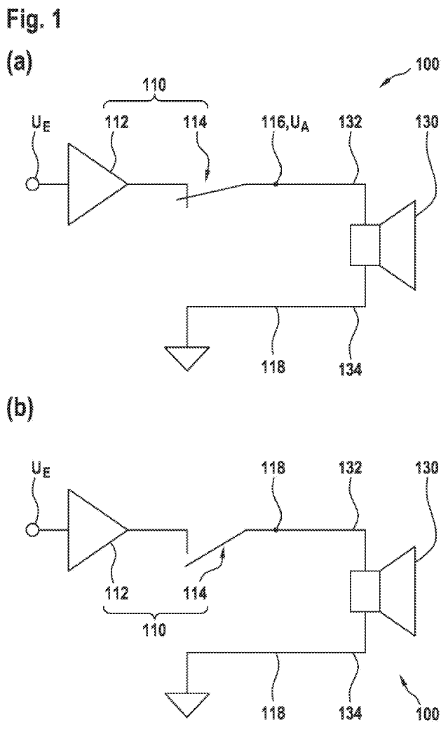

FIG. 1 schematically shows a sound reinforcement system 100 not according to the invention with an audio amplifier 110 for explaining the invention, namely in figure (a) with an active audio amplifier and in figure (b) with an inactive audio amplifier. The audio amplifier 110 is equipped with an amplifier unit 112 and an output relay 114 that extends to an amplifier output terminal 116. In addition, the audio amplifier 110 is equipped with a ground output terminal 118.

In addition to the audio amplifier 110, the sound reinforcement system 100 is, by way of example, equipped with a speaker 130 having one terminal connected to the amplifier output terminal 116 via a line 132 and another terminal connected to the ground output terminal 118 via a line 134.

In figure (a), audio amplifier 110 is active or switched to active. In this case, an input signal U_{E}, which is to be amplified, is present at one input terminal (a second, typically present input terminal is not shown here for the sake of clarity). The audio amplifier 110 outputs an appropriately amplified signal as an output signal U_{A} at the amplifier output terminal 116, so that the speaker is operated. A power supply is not shown here. The output relay 114 is configured here as a normally closed contact, i.e., in the active state of the audio amplifier 110 shown, the output relay 114 is closed.

In figure (b), the audio amplifier 110 is inactive or switched to inactive. This means that the output relay 114 is open; an input signal U_{E} may still be present, but no output signal U_{A} is output at the amplifier output terminal 116.

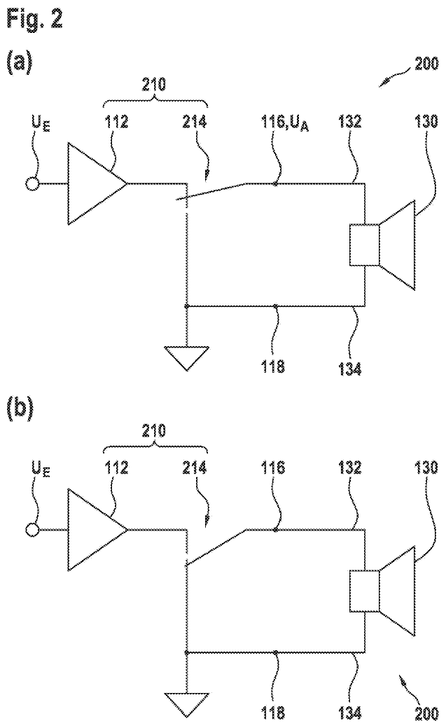

FIG. 2 schematically shows another sound reinforcement system 200 not according to the invention with an audio amplifier 210 for explaining the invention, namely in figure (a) with an active audio amplifier and in figure (b) with an inactive audio amplifier. The difference to the sound reinforcement system 100 according to FIG. 1 lies here only in the audio amplifier 210 which, in contrast to the audio amplifier 110, is equipped with an output relay 214 which is configured as a changeover switch, i.e., connects the amplifier output terminal 116 (or the loudspeaker line connected to it) either to the output signal or to ground. The amplifier unit 112 may be identical, for example. The remaining components correspond to those shown in FIG. 1.

In figure (a), the audio amplifier 210 is active or switched to active. Here the situation does not differ from that in FIG. 1, there figure (a). In figure (b), the audio amplifier 210 is inactive or switched to inactive. This means that the output relay 214 is switched over to close the normally closed contact, connecting the amplifier output terminal 116 to the ground output terminal 118 so that both lines 132, 134 of the speaker 130 are connected to ground. Here, too, an input signal U_{E} may still be present, but no output signal U_{A} is output at the amplifier output terminal 116.

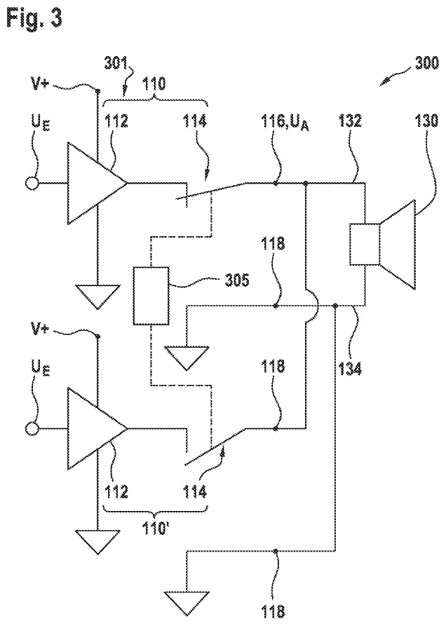

FIG. 3 schematically illustrates another sound reinforcement system 300 not according to the invention. The sound reinforcement system 300 is basically the same as that shown in FIG. 1, but in addition to the audio amplifier 110, another audio amplifier 110′ is provided which is similar in function and also in construction to the audio amplifier 110. Supplementary to FIG. 1, a power supply source V+ is shown for the audio amplifier 110. A separate power supply source V′+ is provided for the audio amplifier 110′.

The speaker 130 is also connected to the audio amplifier 110′ in addition to the audio amplifier 110, so that the two audio amplifiers 110, 110′ are connected in parallel.

In the case shown, the audio amplifier 110 is switched to active, while the audio amplifier 110′ is switched to inactive. This can be seen from the corresponding positions or switching states of the output relays 114, which are each configured as normally closed contacts. Here, the two audio amplifiers 110, 110′ are now part of an audio amplifier arrangement 301 which, by way of example, is also equipped with a circuitry 305 (shown only schematically). By means of this circuitry 305, it is possible, when the audio amplifier 110 is switched to active, to switch the audio amplifier 110′ to inactive, for example by opening its output relay 114.

Thus, only the signal U_{A} output from the active audio amplifier 110 is present at the loudspeaker 130, and regular operation can be performed. Now, for example, if a defect occurs in the audio amplifier 110 or its amplifier unit 112, or its power supply source V+ breaks down, the audio amplifier 110 becomes inactive, the output relay 114 (of the audio amplifier 110) opens (because, for example, there is no more voltage), so that the audio amplifier 110 no longer outputs a signal. By means of the circuitry 305, this can be detected and the output relay 114 of the audio amplifier 110′ can be automatically closed. Thus, the audio amplifier 110′ now outputs the signal U_{A} which it generates from the applied input signal U_{E} in the same way as the audio amplifier 110 did before.

In the simplest case, the circuitry 305 is, for example, a static signal line that allows the active audio amplifier to put the other audio amplifier into standby by sending a “high” signal. In the event of a fault, the signal line is pulled to “low” (or in the event of a complete failure, this is done passively by failure of the internal power supply). However, the circuitry 305 can also be done by a data communication, also this can be a higher-level monitoring unit.

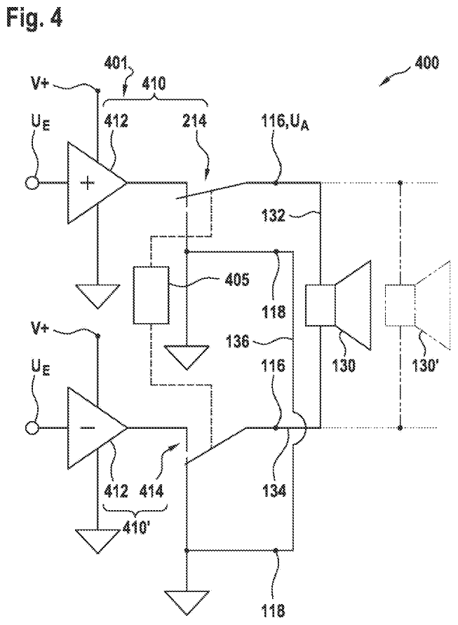

FIG. 4 schematically illustrates a sound reinforcement system 400 according to the invention in a preferred embodiment. The sound reinforcement system 400 is similar to that of FIG. 3, but instead of the audio amplifier 110, an audio amplifier 410 with amplifier unit 412 is provided, but the output relay 214 is configured as a changeover switch. In addition, a further audio amplifier 410′ is provided, which is basically similar to the audio amplifier 410 in its function and also in its structure. As shown in FIG. 3, a power supply source V+ is shown for the audio amplifier 410. A separate power supply source V′+ is provided for the audio amplifier 410′. Both audio amplifiers are part of an audio amplifier arrangement 401.

Here, the loudspeaker 130 is connected to the two amplifier output terminals 116 of the two audio amplifiers 410, 410′ by means of both terminals with lines 132, 134, and the two ground output terminals 118 are connected by means of a line 136.

In addition, a further loudspeaker 130′ is indicated which is connected to the two audio amplifiers 410, 410′ in parallel with loudspeaker 130 so that it can also be controlled via them. It goes without saying that even more loudspeakers and especially a whole loudspeaker line can be connected in this way.

In the case shown, the audio amplifier 410 is switched to active, while the audio amplifier 410′ is inactive. This can be seen from the corresponding positions or switching states of the output relays 214, which are each configured as changeover switches. In this case, the two audio amplifiers 410, 410′ are now part of an audio amplifier arrangement 401 which, by way of example, is also equipped with a circuitry 405 which can be basically similar to the circuitry 305. By means of this circuitry 405, when the audio amplifier 410 is switched to active, it is possible to switch the audio amplifier 410′ to inactive, for example by switching its output relay 214.

Thus, only the signal U_{A} output by the active audio amplifier 410 is present at the loudspeaker 130 (and likewise at the loudspeaker 130′), and regular operation can take place. Now, for example, if a defect occurs in the audio amplifier 410 or its amplifier unit 112, or its power supply source V+ breaks down, the audio amplifier 410 becomes inactive, the output relay 214 (of the audio amplifier 410) switches over (because, for example, there is no more voltage), so that the audio amplifier 410 no longer outputs a signal. By means of the circuitry 405, this can be detected and the output relay 214 of the audio amplifier 410′ can be automatically closed (or switched over). Thus, the audio amplifier 410′ now outputs the signal U_{A}, which it generates from the applied input signal U_{E} in the same way as the audio amplifier 410 did before.

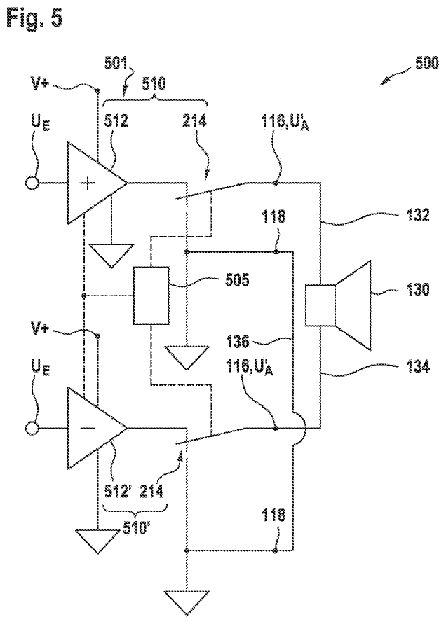

Optionally, it may be provided that the audio amplifier 410′ outputs an inverted signal. The input signal U_{E} can be amplified, e.g., in the audio amplifier (e.g., DSP) in in-phase or in anti-phase (analog or digital by appropriate signal processing), expressing the polarity between output and input signal. An opposite-phase amplification is indicated here with a minus symbol (for audio amplifier 410′), an in-phase amplification with a plus symbol (for audio amplifier 410). This embodiment then also permits preferred parallel operation at the same time, as described with reference to FIG. 5.

FIG. 5 schematically illustrates a sound reinforcement system 500 according to the invention in another preferred embodiment. The sound reinforcement system 500 is similar to that of FIG. 4, but instead of audio amplifiers 410, 410′, audio amplifiers 510, 510′ with amplifier units 512 and 512′ respectively are provided here, but both output relays 214 are also configured as changeover switches here. Both audio amplifiers are part of an audio amplifier arrangement 501.

Both audio amplifiers 510, 510′ can be basically the same in their function and also in their construction, but one of them outputs an inverted signal, as was also described for FIG. 4. The additional speaker 130′ is not shown here, but may be provided as well.

In the case shown, both audio amplifiers 510, 510′ are switched to active in such a way that a signal U′_{A} is output in each case which has, for example, only half the value of an actual desired level (voltage value). Due to the series connection and the inverted operation, the full level is still present at speaker 130.

The two audio amplifiers 510, 510′ are now here part of an audio amplifier arrangement 501, which, by way of example, is also equipped with a circuitry 505. Now, for example, if a defect occurs in the audio amplifier 510 or its amplifier unit 512, or its power supply source V+ breaks down, the audio amplifier 510 becomes inactive, the output relay 214 (of the audio amplifier 512) switches over (because, for example, there is no more voltage), so that the audio amplifier 510 no longer outputs a signal. By means of the circuitry 505 this can be detected and the audio amplifier 510′ can be switched automatically in such a way that it outputs the signal with full level; the full level is thus still present at the loudspeaker 130.

Overall, the invention thus proposes a particularly simple and cost-effective way of designing a sound reinforcement system with redundancy, at least with regard to the audio amplifiers.

1. A sound reinforcement system (400, 500) comprising a loudspeaker (130) and two audio amplifiers (410, 410′, 510, 510′), wherein each audio amplifier (410, 410′, 510, 510′) is equipped with an output relay (214), which extends to an amplifier output terminal (116) of the associated audio amplifier, as well as a ground output terminal (118);
wherein each of two terminals of the loudspeaker (130) is connected to one of the amplifier output terminals;
wherein the ground output terminals (118) of the two audio amplifiers (410, 410′, 510, 510′) are connected to one another and/or to ground.

2. The sound reinforcement system (400, 500) according to claim 1, which is configured such that the two audio amplifiers are connectable to mutually different power supply sources (V+, V′+).

3. The sound reinforcement system (300, 400, 500) according to claim 2, wherein the two audio amplifiers are connected to mutually different power supply sources (V+, V′+), wherein the two different power supply sources comprise two different mains voltage supplies or a mains voltage supply and a stand-alone power supply source.

4. The sound reinforcement system (400, 500) according to claim 1, adapted for use in a public address sound reinforcement system or a professional sound reinforcement system.

5. The sound reinforcement system (400) according to claim 1, comprising one or more further loudspeakers (130′) each connected in parallel with the loudspeaker (130) to the amplifier output terminals (116).

6. The sound reinforcement system (400, 500) according to claim 1, wherein the output relays (214) each connect the amplifier output terminal (116) to the audio amplifier ground output terminal (118) when the associated audio amplifier is inactive.

7. The sound reinforcement system (400, 500) according to claim 1, wherein the two audio amplifiers (410, 410′, 510, 510′) are arranged such that one of the two audio amplifiers outputs a signal at the amplifier output terminal (116) that is inverted with respect to the other audio amplifier.

8. A method of operating a sound reinforcement system (400, 500) comprising a loudspeaker (130), two audio amplifiers (410, 410,′ 510, 501′) each having an output relay (214) which extend to an amplifier output terminal (116) of the associated audio amplifier, the loudspeaker (130) being connected to the amplifier output terminals (116),
wherein each of the two audio amplifiers (410, 410′, 510, 501′) is respectively operated such that when active, the output relay (214) is closed so that a signal (U′_{A}, U_{A}) is present at the amplifier output terminal, and when inactive, the output relay is switched such that no signal is present at the amplifier output terminal (116),
wherein, when at least one of the two audio amplifiers is switched to active, and when a switched-to-active audio amplifier becomes inactive, the respective other audio amplifier is automatically operated in such a way that a signal with a higher output voltage than before is present at the associated amplifier output terminal.

9. The method according to claim 8, wherein when one of the two audio amplifiers is switched to active, the respective other audio amplifier is switched to inactive, and when a switched-to-active audio amplifier becomes inactive, the respective other audio amplifier is automatically switched to active.

10. The method according to claim 8, wherein the two audio amplifiers are switched between active and inactive at predetermined and/or regular, timed intervals.

11. The method according to claim 8, wherein, if the two audio amplifiers are each switched to active so that a signal (U′_{A}) with less than a full output voltage is present at the associated amplifier output terminal (116), and one of the two switched-to-active audio amplifiers becomes inactive, the respective other audio amplifier is automatically operated in such a way that a signal with a higher output voltage than before is present at the associated amplifier output terminal.

12. (canceled)
